(19) United States
(12) Patent Application Publication
(10) Pub. No.: US 2012/0073503 A1
(43) Pub. Date: Mar. 29, 2012

(54) PROCESSING SYSTEMS AND APPARATUSES HAVING A SHAFT COVER

(76) Inventors: Juno Yu-Ting Huang, Santa Clara, CA (US); Sang Won Kang, San Jose, CA (US); David H. Quach, San Jose, CA (US); Wei-Yung Hsu, Santa Clara, CA (US)

(21) Appl. No.: 13/098,241

(22) Filed: Apr. 29, 2011

Related U.S. Application Data
(60) Provisional application No. 61/386,447, filed on Sep. 24, 2010.
(60) Provisional application No. 61/407,874, filed on Oct. 28, 2010.

(51) Int. Cl. C30B 25/08; C30B 25/12

(52) U.S. Cl. 118/725; 118/728

(57) ABSTRACT

Apparatus and systems are disclosed for processing a substrate. In an embodiment, a system includes a processing chamber, which includes a substrate support to support the substrate. The chamber further includes a plate member positioned below the substrate support and designed to improve heating efficiency within the processing chamber. The processing chamber further includes a lower dome positioned below the plate member. The plate member is designed to prevent a coating from being deposited on the lower dome during processing conditions. The plate member is designed to prevent particles and debris from falling below the plate member. The plate member is designed to improve heating uniformity between the plate member and the substrate within the processing chamber.

### RELATED APPLICATIONS

This application claims the benefit of Provisional Application No. 61/386,447, filed Sep. 24, 2010, and Provisional Application No. 61/407,874, filed Oct. 28, 2010, which are both incorporated herein by reference.

### FIELD

This invention relates to a processing apparatus and, more particularly, to the use of a shaft cover to prevent coating of a lower region of the processing apparatus.

### DESCRIPTION OF RELATED ART

Group III-V materials are playing an ever increasing role in the semiconductor and related, e.g. light-emitting diode (LED), industries. While LEDs employing multiple quantum well (MQW) structures epitaxially grown on a substrate are a promising technology, epitaxial growth of such structures is difficult because of the large number of very thin material layers formed and the dependence of emission wavelength on the material and physical characteristics of those layers.

The material and/or physical characteristics of an MQW structure are dependent on the growth environment within an epitaxy chamber which can vary over a number batches or runs processed. Also, there is severe lower dome coating of a processing apparatus for n-GaN growth process by using hydride vapor phase epitaxy (HVPE) and metal-organic chemical vapor deposition (MOCVD) growth technologies. In addition, the MQW and p-GaN processes also have lower dome coating issues. It has also been discovered that some unwanted debris from the chamber or gaskets fall to the lower dome. During the high temperature operation, the fall-on debris will melt thus damaging and polluting the lower dome surface.

### BRIEF DESCRIPTION OF THE DRAWINGS

Embodiments of the present invention is illustrated by way of example, and not by way of limitation, in the figures of the accompanying drawings, in which:

FIG. 1 illustrates a cross-sectional view of a processing system or apparatus 100 in accordance with certain embodiments;

FIGS. 2A-2G illustrate certain embodiments of a plate member;

FIG. 3A illustrates a top view of a plate member 300 (e.g., shaft cover) in accordance with one embodiment;

FIG. 3B illustrates a side view of a plate member 350 (e.g., shaft cover) in accordance with one embodiment;

FIG. 3C illustrates a top view of a patterned plate member 360 (e.g., shaft cover) in accordance with one embodiment;

FIG. 3D illustrates an exploded top view of a patterned plate member 370 (e.g., shaft cover) in accordance with one embodiment;

FIG. 4A illustrates a top view of a plate member 400 (e.g., shaft cover) in accordance with one embodiment;

FIG. 4B illustrates a side view of a plate member 420 (e.g., shaft cover) having lips 421 and 422 in accordance with one embodiment;

FIG. 4C illustrates a side exploded view of a plate member 440 (e.g., shaft cover) having a lip 441 in accordance with one embodiment;

FIG. 5 illustrates a cross-sectional view of a processing system in accordance with one embodiment;

FIG. 6A illustrates a cross-sectional view of a processing system without a shaft cover and FIG. 6B illustrates a cross-sectional view of a processing system with a shaft cover in accordance with one embodiment;

FIG. 7A illustrates a cross-sectional view of a processing system without a shaft cover that shows a velocity profile and FIG. 7B illustrates a cross-sectional view of a processing system with a shaft cover that shows a velocity profile in accordance with one embodiment;

FIG. 8 illustrates an HVPE apparatus in accordance with one embodiment;

FIG. 9 illustrates an MOCVD apparatus in accordance with an embodiment;

FIG. 10 illustrates an MOCVD apparatus in accordance with another embodiment;

FIG. 11 illustrates a correlation between carrier temperature and photoluminescence (PL) for LEDs in accordance with one embodiment;

FIG. 12 illustrates a cross-sectional view of a device in accordance with one embodiment; and

FIG. 13 illustrates a physical structure of a cluster tool schematically in one embodiment.

### SUMMARY

Apparatus and systems are disclosed for processing a semiconductor substrate. In an embodiment, a system includes a processing chamber, which includes a substrate support to support the substrate. The chamber further includes a plate member positioned below the substrate support and designed to improve heating efficiency within the processing chamber. The processing chamber further includes a lower dome positioned below the plate member. The plate member is designed to prevent a coating from being deposited on the lower dome during processing deposition conditions. The plate member is designed to prevent particles and debris from falling below the plate member.

In another embodiment, the processing chamber further includes a heating source to generate heat and transmit the heat towards the substrate to heat the substrate. The plate member is designed to improve heating uniformity between the plate member and the substrate within the processing chamber. The plate member includes an upper surface and a lower surface. At least one of these surfaces may have a convex or concave shape in order to create a lens effect and improve the heating uniformity within the processing chamber. At least one of these surfaces may have a pattern that refracts light in order to improving the heating uniformity within the processing chamber.

### DETAILED DESCRIPTION

In the following description, numerous details are set forth. It will be apparent, however, to one skilled in the art, that the present invention may be practiced without these specific details. In some instances, well-known methods and devices are shown in block diagram form, rather than in detail, to avoid obscuring the present invention. Reference throughout this specification to “an embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

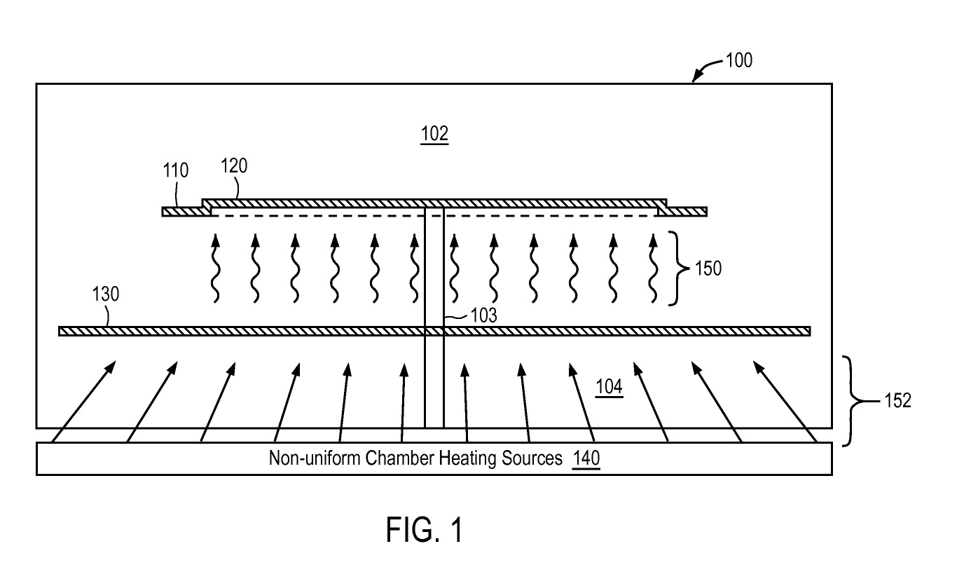

FIG. 1 illustrates a cross-sectional view of a processing system or apparatus 100 in accordance with certain embodiments. The processing system 100 includes a substrate support (e.g., susceptor 110) for holding a carrier 120. Alternatively, the susceptor may be replaced with an edge ring. Substrates (e.g., semiconductor substrates, Silicon substrates, III-V material substrates) may be located on the carrier for a processing operation (e.g., deposition, chemical vapor deposition, MOCVD, APCVD, HYPE, etc.). Non-uniform chamber heating sources 140 provide heat to the substrate during processing operations.

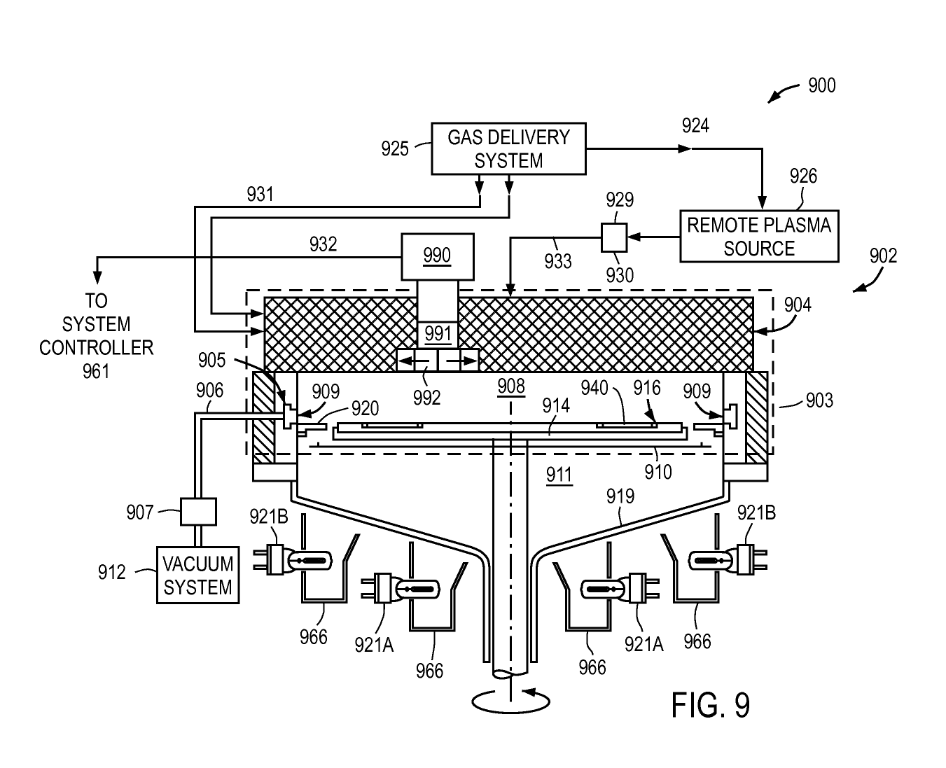

The system 100 includes an upper processing region 102 above a plate member (e.g., shaft cover) 130 and a lower processing region 104 below the plate member. A support member (e.g., shaft) 103 supports the plate member 130 and the suspector 110. The plate member 130 remains a certain distance below the suspector 110 and carrier 120. A plate member 130 prevents the coating of chamber components that are below the shaft cover. For example, a plate member (e.g., shaft cover 910) in a processing system 900 illustrated in FIG. 9 in accordance with one embodiment prevents the coating of a lower dome 919. The processing system 900 (e.g., MOCVD system) will be discussed in more detail below.

Returning to FIG. 1, the plate member 130 provides a more uniform thermal channel 150 in comparison to the non-uniform thermal channel 152 provided by the non-uniform chamber heating sources. This leads to better substrate to substrate center/edge uniformity. The plate member 130 additionally prevents debris from falling below the plate member 130 onto the heating sources 140. The plate member 130 also enhances the heating efficiency of the processing region 100. The plate member 130 could be made from Quartz, Molybdenum, Tungsten, or Silicon Carbide depending on processing conditions.

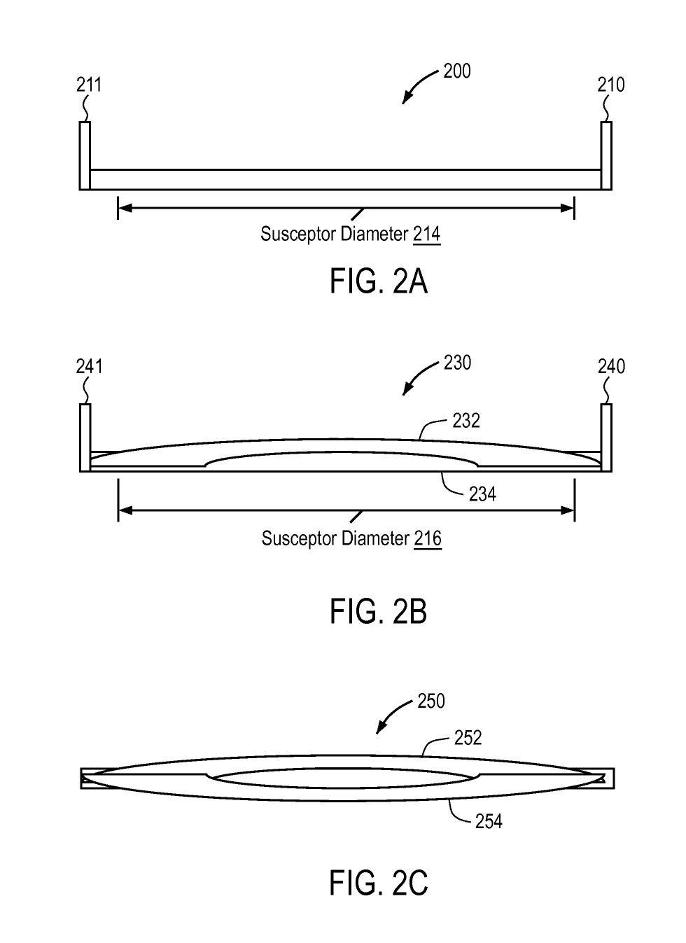

FIGS. 2A-2G illustrate certain embodiments of a plate member. FIG. 2A illustrates a plate member 200 having substantially vertical members 210 and 211 (e.g., substantially vertical lips) near an outer edge of the plate member. These lips prevent unwanted particles/debris from falling onto a region below the plate member (e.g., lower dome 4119). In one embodiment, a susceptor has a diameter 214 of 355.6 mm and the plate member 200 is designed to have a larger diameter than the susceptor diameter.

FIG. 2B illustrates a plate member 230 having substantially vertical members 240 and 241. These vertical members or lips prevent unwanted particles/debris from falling onto a region below the plate member (e.g., lower dome 4119). In one embodiment, a susceptor has a diameter 216 of 355.6 mm and the plate member 230 is designed to have a larger diameter than the susceptor diameter. The plate member 230 has a convex upper surface 232 and a flat or planar lower surface 234. The heating efficiency in the chamber can be engineered by designing the surface of the plate member (e.g., shaft cover) to create a lens effect.

FIG. 2C illustrates a plate member 250 having a convex upper surface 252 and a convex lower surface 254 in accordance with one embodiment. For example, to obtain a higher temperature in a center area of a chamber or substrate a plate member with a convex surface is used. Alternatively, a concave lower and/or upper surface may be used for additional control of the heat efficiency. FIGS. 2D and 2E illustrate examples of plate members with at least one concave surface. The plate member 260 has a concave upper surface 261 and a flat or planar lower surface 262. FIG. 2E illustrates a plate member 270 having a concave upper surface 271 and a concave lower surface 272 in accordance with one embodiment.

By designing the upper or lower surface of the plate member to be convex or concave, different types of heating patterns can be engineered. For example, in FIG. 1 the thermal channel 150 can be designed with different heating patterns such as inner area hotter, intermediate area hotter, or edge area hotter than other areas of a chamber or substrate. These different heating patterns and heating efficiencies may be needed because of different processes, different wafer sizes, and different semiconductor substrates.

FIGS. 2F and 2G illustrate ripple patterned plate members. A ripple patterned plate member 280 includes a ripple patterned upper surface 281 and a flat or planar lower surface 282 in accordance with one embodiment. The upper surface has a pattern with a pitch 283 of approximately 1-5 mm and a height 285 of approximately 0.1-2 mm. FIG. 2G illustrates an exploded view of a ripple patterned plate member 290 in accordance with one embodiment. Radiation is shown with light rays in the form of lines 294. The radiation enters a lower planar surface 292 of the plate member and refracts from an upper patterned surface 291 of the plate member 290. Refraction of the radiation enhances cross talk along a radial direction of a heating carrier that is above the plate member 290. The refraction of the radiation improves the temperature uniformity in the radial direction of the heating carrier.

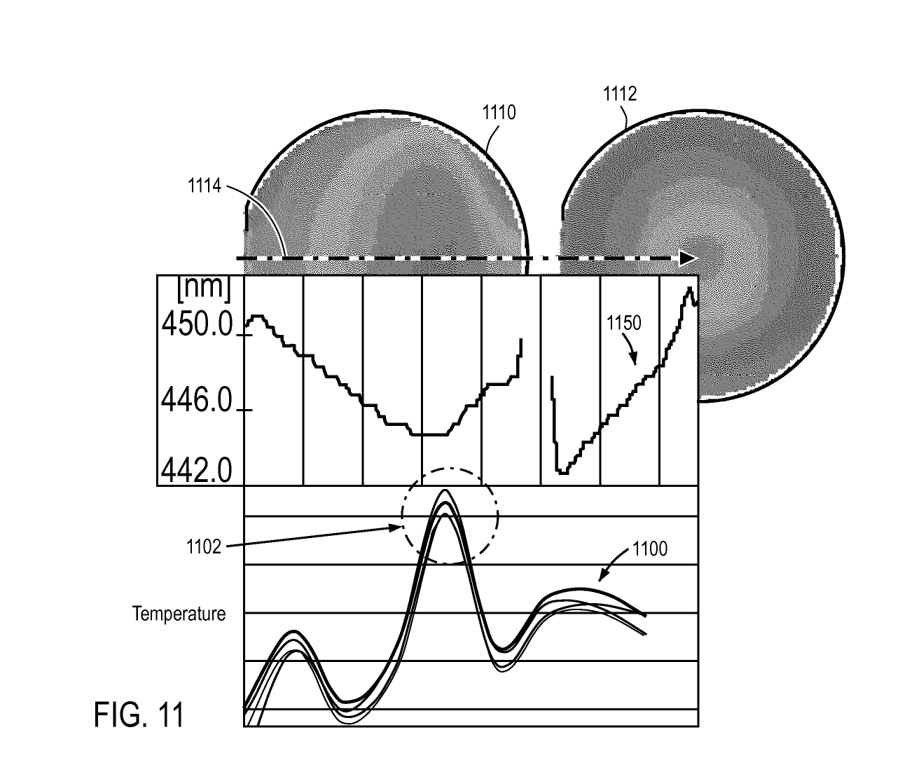

FIG. 11 illustrates a correlation between carrier temperature and photoluminescence (PL) for LEDs in accordance with one embodiment. The carrier temperature 1100 is plotted across the radial direction 1114 of substrate 1110 and 1112. The peak 1102 in the carrier temperature 1100 is caused by a corresponding high light density from a heating source (e.g., lamp bank). The carrier temperature 1100 across these substrates mirrors corresponding PL measurements in nanometers for LEDs across these substrates. Thus, improving the temperature uniformity in the radial direction of a carrier using a plate member will also improve the uniformity of the PL measurements of LEDs in the radial direction of the carrier.

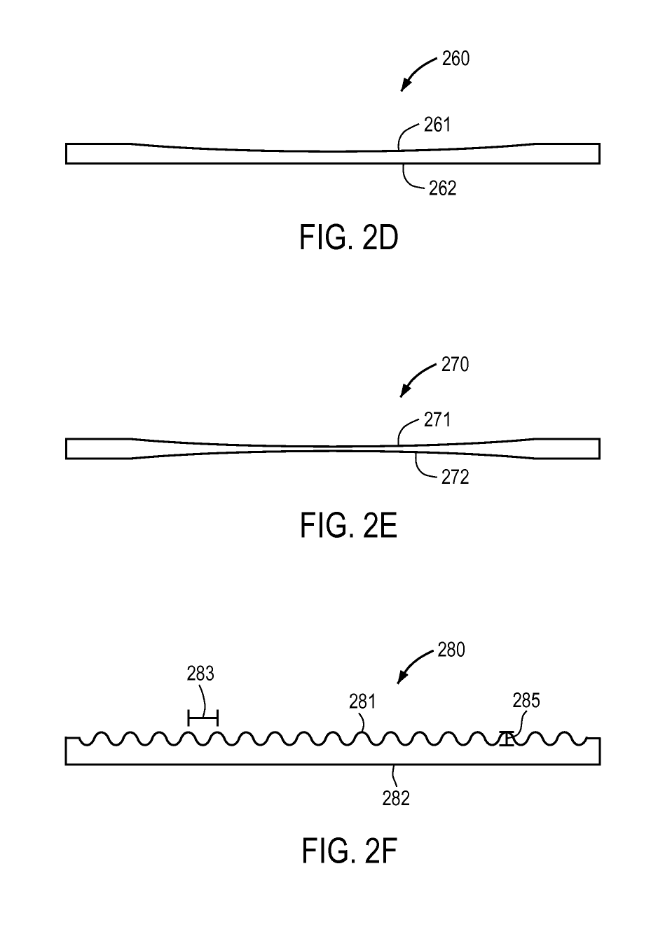

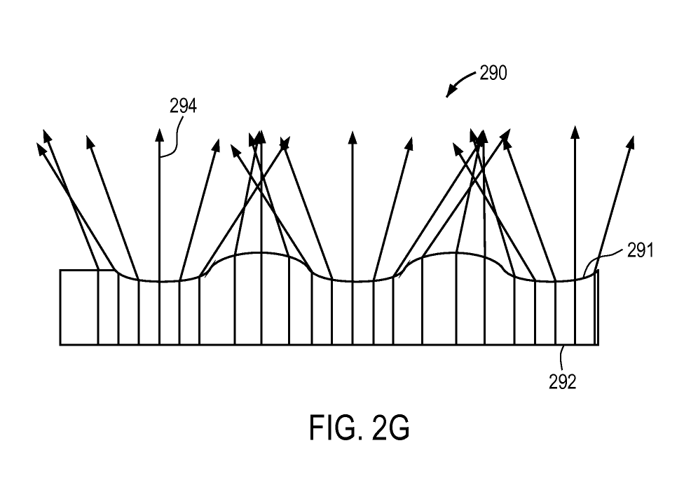

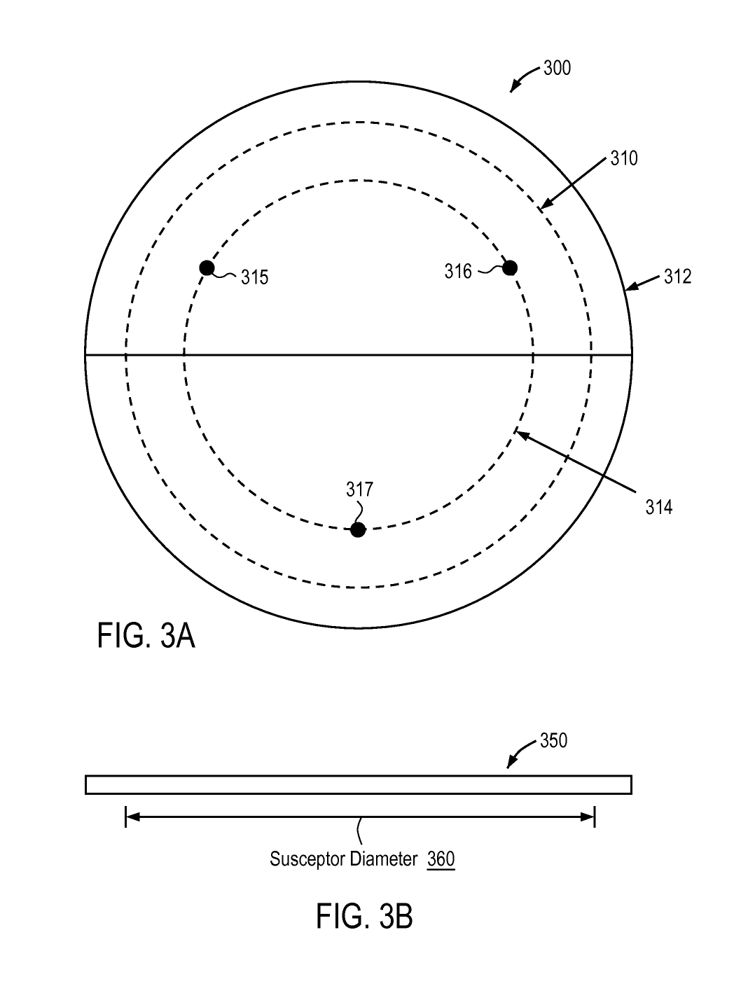

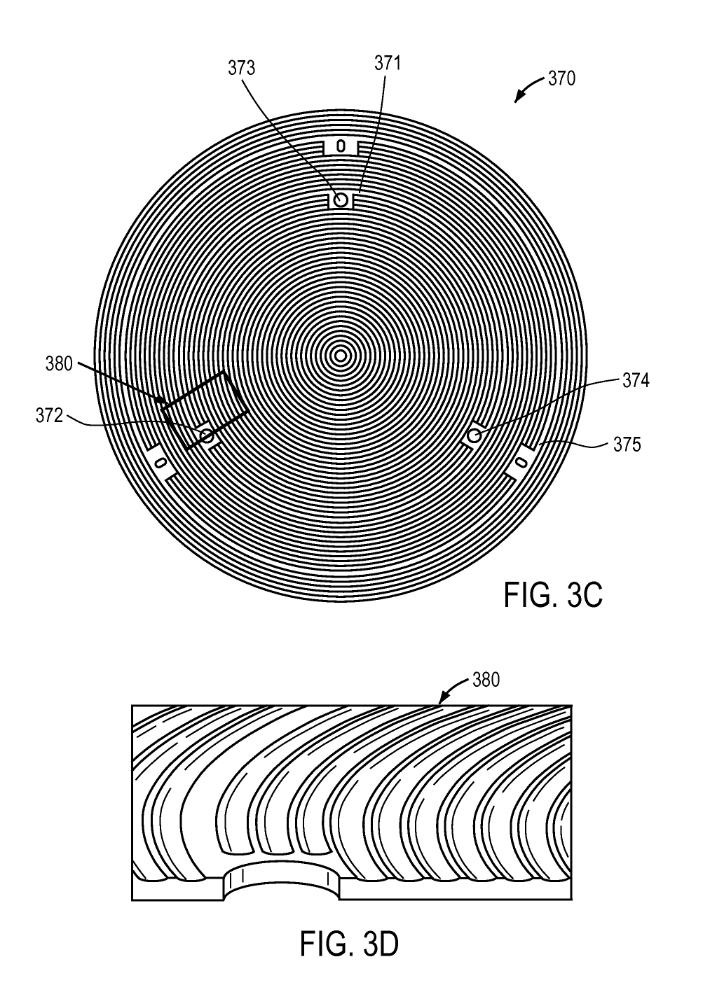

FIG. 3A illustrates a top view of a plate member 300 (e.g., shaft cover) in accordance with one embodiment. The points 315-317 of an inner circle 314 represent locations where a support member (e.g., shaft, pins) attaches to the member 300. The inner circle 314 may have a diameter of approximately 253 mm. An intermediate circle 310 is associated with a diameter of a suspector (e.g., diameter of approximately 356 mm). The plate member 300 is designed with a diameter (e.g., 356 to 420 mm) larger than the diameter of the suspector.

FIG. 3B illustrates a side view of a plate member 350 (e.g., shaft cover) in accordance with one embodiment. The plate member 350 prevents coating of a region below it (e.g., lower dome 919). The plate member 350 may have a thickness between 2 mm and 20 mm depending on a particular chamber and processing operations. The plate member 350 is designed with a diameter (e.g., 356 to 420 mm) larger than the diameter of the suspector 360.

FIG. 3C illustrates a top view of a patterned plate member 370 (e.g., shaft cover) in accordance with one embodiment. The dimensions of the plate member 370 may be similar to the dimensions of the plate member 300 discussed above. The points 372-374 of an inner circle 371 represent locations where a support member (e.g., shaft, pins) attach to the member 370. The inner circle 371 may have a diameter of approximately 253 mm. An intermediate circle 375 is associated with a diameter of a suspector (e.g., diameter of approximately 356 mm). The plate member 370 is designed with a diameter (e.g., 356 to 420 mm) larger than the diameter of the suspector.

FIG. 3D illustrates an exploded top view of a patterned plate member 380 (e.g., shaft cover 370) in accordance with one embodiment. The ripple pattern causes refraction of radiation as illustrated in FIG. 2G.

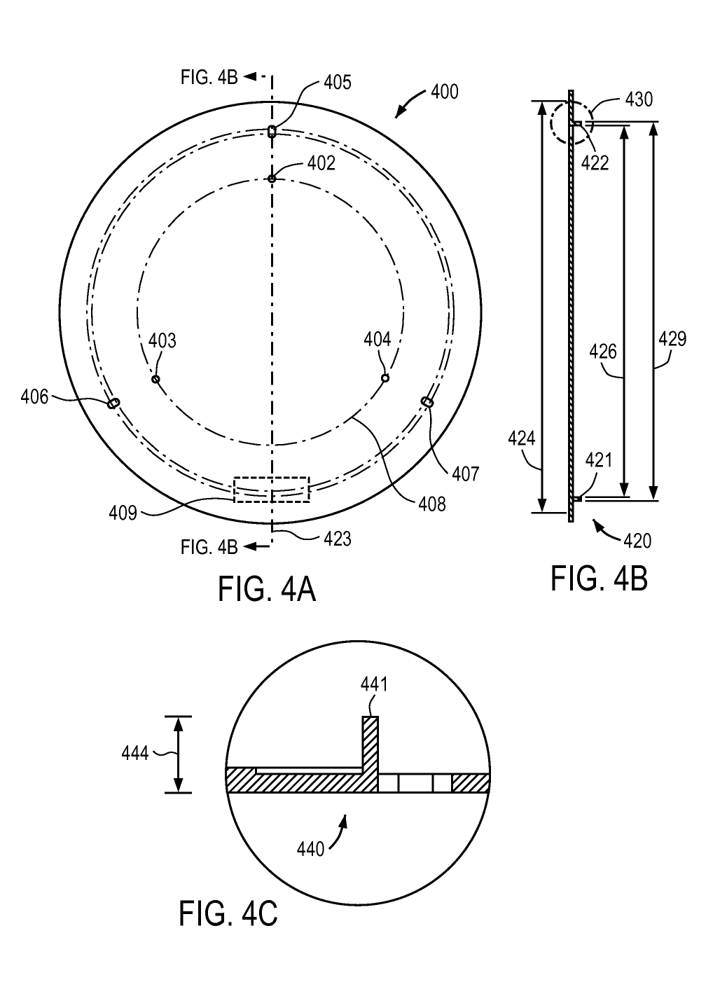

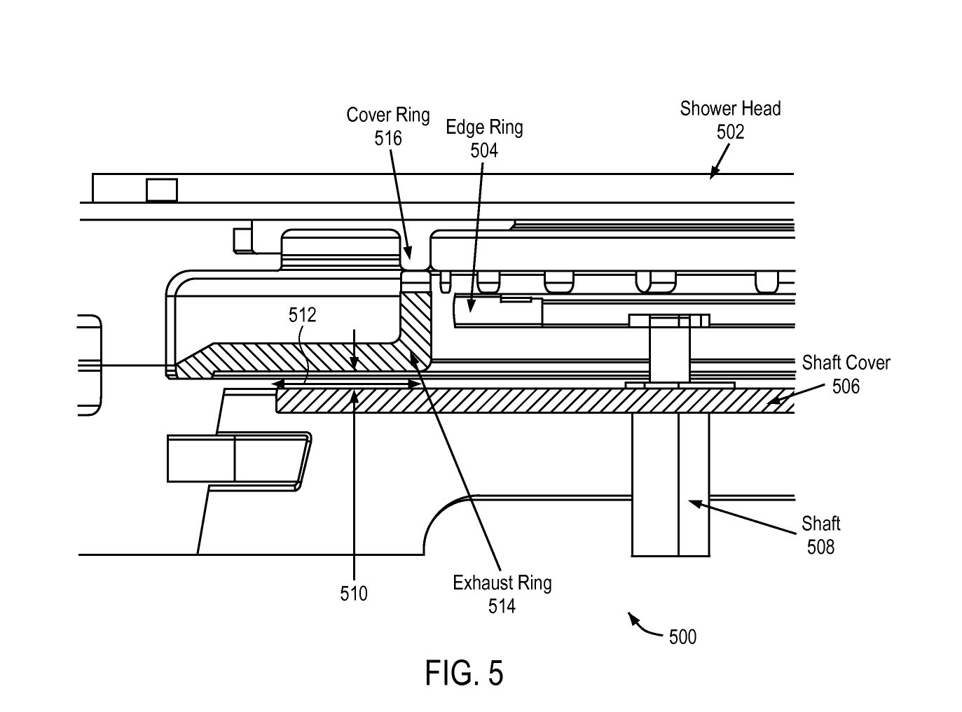

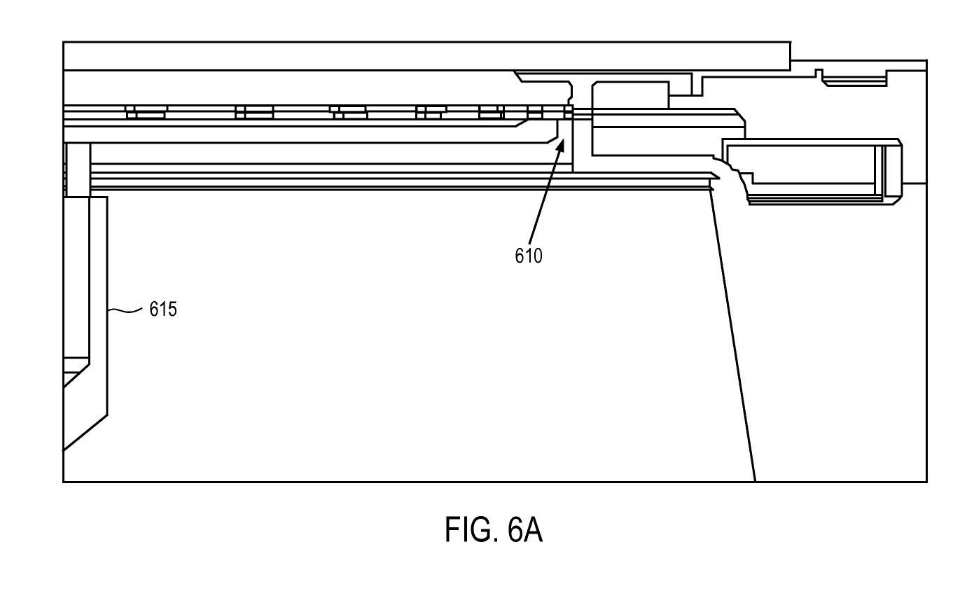

FIG. 4A illustrates a top view of a plate member 400 (e.g., shaft cover) in accordance with one embodiment. The points 402-404 of an inner circle and slots 405-407 represent locations where a support member (e.g., shaft, pins) attaches to the baffle plate member 400. The inner circle 408 may have a diameter of approximately 254 mm. An intermediate circle 409 may have a diameter of approximately 339 mm. The baffle plate member may have an outer diameter (e.g., 400 mm) larger than the diameter of the suspector.

FIG. 4B illustrates a side view of a plate member 420 (e.g., cross-sectional view 423 of shaft cover 400) having lips 421 and 422 in accordance with one embodiment. The plate member 420 may have a thickness between 2 mm and 20 mm depending on a particular chamber and processing operations. The member 420 may have a beveled edge diameter 424 of approximately 390 mm, an inner diameter 426 between inner portions of lips may be approximately 354 mm, and an outer diameter 425 between outer portions of lips may be approximately 359 mm.

FIG. 4C illustrates a side exploded view 440 of a plate member 440 (e.g., cross-sectional view 430 of shaft cover 420 in FIG. 4B) having a lip 441 in accordance with one embodiment. The plate member and lip in combination may have a thickness 444 between 8 mm and 30 mm (e.g., 10.8 mm) depending on a particular chamber and processing operations.

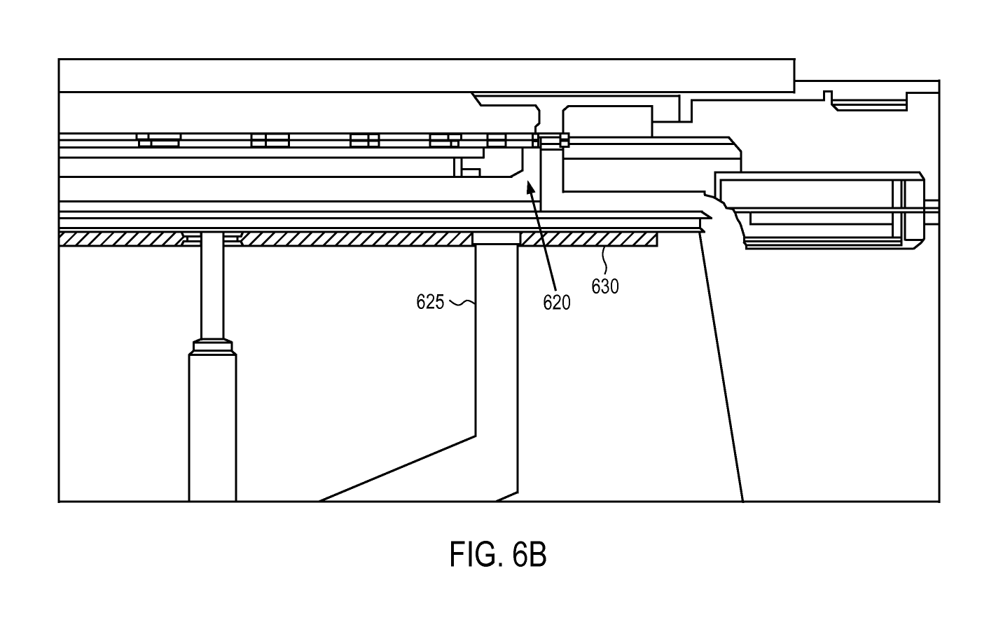

FIG. 5 illustrates a cross-sectional view of a processing system in accordance with one embodiment. The system 500 includes a showerhead 502 for delivering process gases in a processing volume, an edge ring 504 for supporting a substrate support (e.g., carrier), a shaft cover 506, and a shaft 508. Alternatively, the edge ring may be replaced with a susceptor. An overlap 512 illustrates that the shaft cover 506 may extend beyond an outer edge of an edge ring 504 (or susceptor). The overlap 512 can vary and may be approximately 10-50 mm (e.g., 20 mm). The shaft cover 506 is spaced a certain distance 510 (e.g., approximately 2.2 mm to 10 mm) below an exhaust ring 514. A cover ring 516 is aligned above the exhaust ring 514.

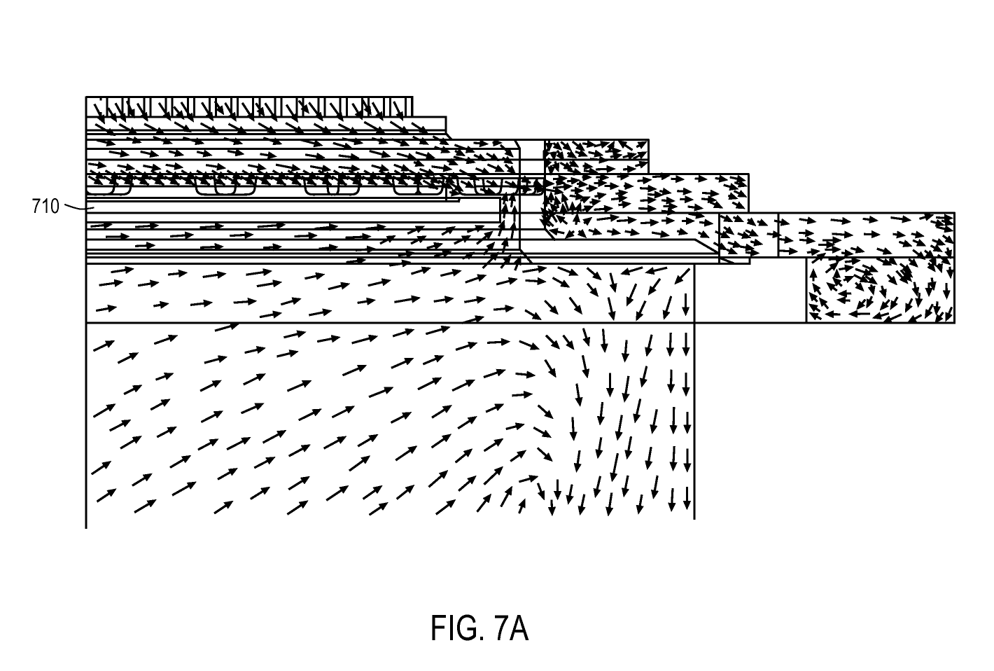

FIG. 6A illustrates a cross-sectional view of a processing system without a shaft cover and FIG. 6B illustrates a cross-sectional view of a processing system with a shaft cover in accordance with one embodiment. Process sensitivity to a gap 610 occurs when the shaft 615 wobbles. The process sensitivity to a gap 620 will be reduced with a shaft cover induced channel as illustrated with the shaft cover 630 that is coupled to the shaft 625 in FIG. 6B.

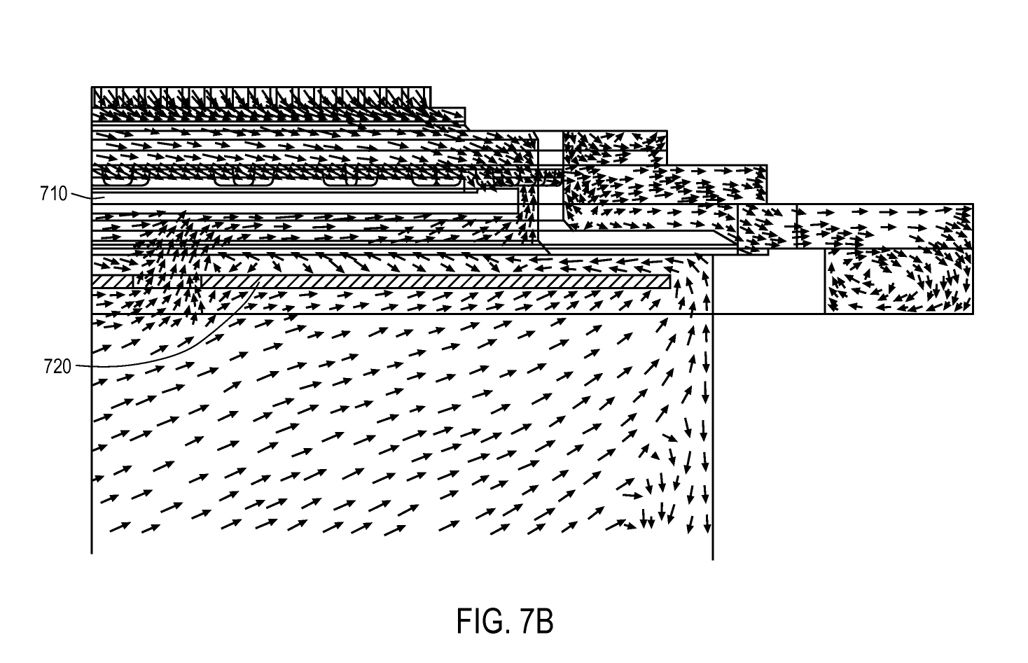

FIG. 7A illustrates a cross-sectional view of a processing system without a shaft cover that shows a velocity profile and FIG. 7B illustrates a cross-sectional view of a processing system with a shaft cover that shows a velocity profile in accordance with one embodiment. The velocity profile, which is illustrated with arrows, is similar or the same above the susceptor 710 for FIGS. 7A and 7B, but below the susceptor 710 it has changed. With the shaft cover 720 illustrated in FIG. 7B, purge flow is more efficiently pumped out from the outer edge of the shaft cover 720 up to the pumping holes. This minimizes the re-circulated flow which may carry residual from the top down to the lower dome. Since the magnitude of the flow is similar or has not changed, residual that previously falls down to the lower dome will likely fall down to the shaft cover. The velocity profile in FIG. 7A has a velocity magnitude of approximately 7.581 m/s while velocity profile in FIG. 7B has a similar velocity magnitude of approximately 7.821. Thus, the shaft covers in FIGS. 6B and 7B will not impact the deposition/growth rate of n-GaN, MQW, and p-GaN layers.

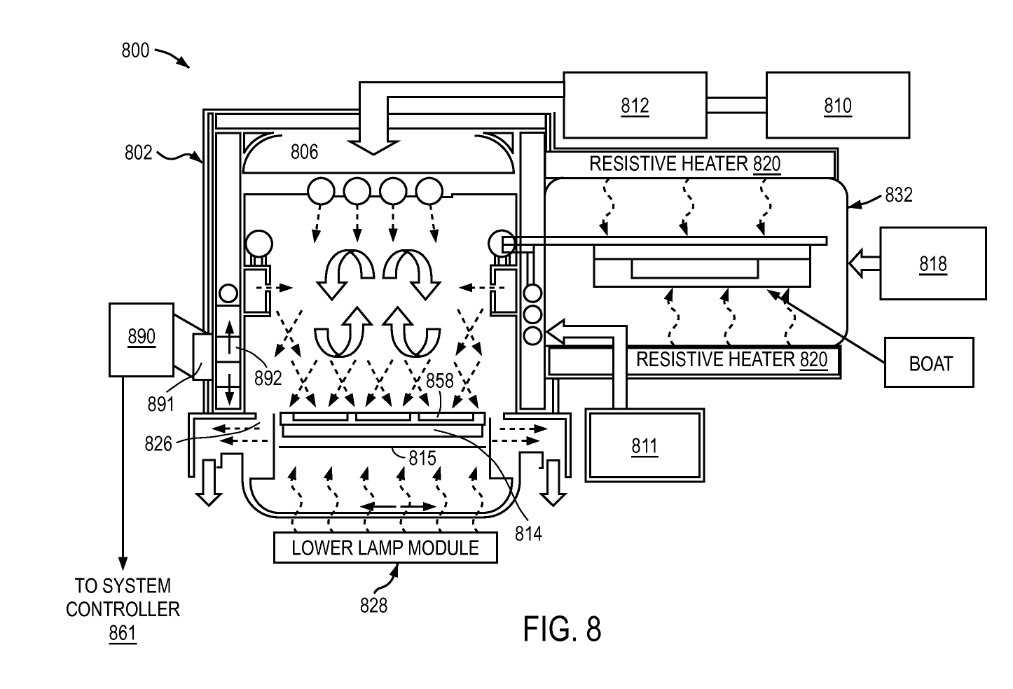

Turning now to FIGS. 8-10, the plate member (e.g., shaft cover) is described in conjunction with exemplary processing systems or apparatuses. A substrate 858 including a GaN base layer, in one embodiment, is provided to an epitaxial deposition chamber. The epitaxy chamber may be as depicted in FIGS. 8-10, or any other commercially available chamber.

The substrate is heated during the recipe stabilization period. For example, an HVPE apparatus 800 depicted in FIG. 8, includes a shutter 892 disposed between the window 891 and the chamber 802. In an exemplary embodiment, a pyrometer 890 is disposed external to the window 891 and upon the shutter 892 opening, temperature readings may begin being sampled. Similarly, in FIG. 9 an MOCVD apparatus configured with in-situ temperature measurement hardware including the pyrometer 990, window 991 and shutter 992 is illustrated.

Referring first to FIG. 8, a processing gas from a first gas source 810 is delivered to the chamber 802 through a gas distribution showerhead 806. In one embodiment, the gas source 810 may include a nitrogen containing compound. In another embodiment, the gas source 810 may include ammonia. In one embodiment, an inert gas such as helium or diatomic nitrogen may be introduced as well either through the gas distribution showerhead 806 or through the walls of the chamber 802 from gas source 811. An energy source 812 may be disposed between the gas source 810 and the gas distribution showerhead 806. In one embodiment, the energy source 812 may include a heater. The energy source 812 may break up the gas from the gas source 810, such as ammonia, so that the nitrogen from the nitrogen containing gas is more reactive.

To react with the gas from the first source 810, precursor material may be delivered from one or more second sources 818. The precursor may be delivered to the chamber 802 by flowing a reactive gas over and/or through the precursor in the precursor source 818. In one embodiment, the reactive gas may include a chlorine containing gas such as diatomic chlorine. The chlorine containing gas may react with the precursor source to form a chloride. In order to increase the effectiveness of the chlorine containing gas to react with the precursor, the chlorine containing gas may snake through the boat area in the region 832 and be heated with the resistive heater 820. By increasing the residence time that the chlorine containing gas is snaked through the region 832, the temperature of the chlorine containing gas may be controlled. By increasing the temperature of the chlorine containing gas, the chlorine may react with the precursor faster. In other words, the temperature is a catalyst to the reaction between the chlorine and the precursor.

In order to increase the reactiveness of the precursor, the precursor may be heated by a resistive heater 820 within the region 832 in a boat. The chloride reaction product may then be delivered to the chamber 802 where it mixes with the nitrogen containing gas to form a nitride layer on the substrate 816 that is disposed on a susceptor 814. In one embodiment, the susceptor 814 may include silicon carbide. The nitride layer may include gallium nitride for example. The other reaction products, such as nitrogen and chlorine, are exhausted through an exhaust 826.

A shaft cover 815 is located below the susceptor 814. The shaft cover 815 and optional vertical members (not shown), if any exist, are both located below the susceptor to not disturb the processing condition above the susceptor. The shaft cover 815 prevents particulars/debris from falling below the shaft cover 815 and also improves the heating efficiency and thermal uniformity of heat generated by lower lamp module 828.

Turning to FIG. 9, a schematic cross-sectional view of an MOCVD chamber which can be utilized in embodiments of the invention is depicted. The MOCVD apparatus 900 shown in FIG. 9 includes a chamber 902, a gas delivery system 925, a remote plasma source 926, a vacuum system 912, and a system controller 961. The chamber 902 includes a chamber body 903 that encloses a processing volume 908. A showerhead assembly 904 is disposed at one end of the processing volume 908, and a substrate carrier 914 is disposed at the other end of the processing volume 908. A lower dome 919 is disposed at one end of a lower volume 911, and the substrate carrier 914 is disposed at the other end of the lower volume 911. The substrate carrier 914 is shown in process position, but may be moved to a lower position where, for example, the substrates 940 may be loaded or unloaded. An exhaust ring 920 may be disposed around the periphery of the substrate carrier 914 to help prevent deposition from occurring in the lower volume 911 and also help direct exhaust gases from the chamber 902 to exhaust ports 909. Additionally, a shaft cover 910 with optional vertical members (e.g., lips), if any exist, are both located below the susceptor to not disturb the processing condition above the susceptor. The shaft cover prevents deposition from occurring in the lower volume 911. There can be severe lower dome coating for n-GaN growth process by using HVPE and MOCVD growth technologies without a shaft cover. In additions, the MQW and p-GaN processes also have lower dome coating issues. The use of shaft cover 910 beneath the process carrier reduces the lower dome coating and does not disturb the process conditions above the process carrier. Besides the lower dome coating by the LED growth process, it was found that some unwanted debris from the chamber or gaskets would also fall to the lower dome. During the high temperature operation, the fall-on debris will melt thus damaging and polluting the lower dome surface. The shaft cover 910 prevents fall-on debris to lower dome.

The lower dome 919 may be made of transparent material, such as high-purity quartz, to allow light to pass through for radiant heating of the substrates 940. The radiant heating may be provided by a plurality of inner lamps 921A and outer lamps 921B disposed below the lower dome 919. Reflectors 966 may be used to help control chamber 902 exposure to the radiant energy provided by inner and outer lamps 921A, 921B. Additional rings of lamps may also be used for finer temperature control of the substrates 940.

The shaft cover 910 improves heating uniformity because the shaft cover also provides a uniform thermal channel between the carrier and the shaft cover. The heating uniformity is improved, which leads to better wafer-to-wafer center/edge uniformity.

The shaft cover also enhances heating efficiency as indicated from the following temperature calibration data in Table 1. Also, with the same temperature setting, the total power feedback gains ˜3 kW in n-GaN growth process, which is favorable for high quality of GaN process.

TABLE 1

| | Without Shaft Cover | | | With Shaft Cover | | | Temperature Gained from | |
|---|---|---|---|---|---|---|---|---|
| Lamp | Temperature (° C.) | | | Temperature (° C.) | | | Shaft Cover (° C.) | |
| Power | Bottom | Bottom | ΔT | Bottom | Bottom | ΔT | ΔT | ΔT |
| (kW) | Inner | Outer | Inner/Outer | Inner | Outer | Inner/Outer | Inner Zone | Outer Zone |
| 45 | 980 | 968 | 12 | 994 | 974 | 20 | 14 | 6 |
| 35 | 891 | 880 | 11 | 909 | 889 | 20 | 18 | 9 |

The growth temperature distribution across the chamber and/or carrier is not uniform in current system design, which causes high wafer-to-wafer non-uniformity in n-GaN, MQW, and p-GaN processes.

In the current growth process, the center of the chamber/carrier usually suffers from lower growth temperature than that in the outer area. Therefore, the increase of the temperature in chamber center area could improve the growth performance, namely, improving wafer-to-wafer uniformity in n-GaN, MQW, and p-GaN processes.

The shaft cover also increases the chamber heating capacity under the same lamp power output, which is favorable for high quality n-GaN process. For example, in Table 1 above, for a Lamp Power of 45 kW, a bottom inner temperature is 980 degrees C. without a bottom cover plate versus 994 degrees C. with a bottom cover plate. Thus, a gain of 14 degrees C. of the growth temperature results from the use of the shaft cover.

Table 1 was tested under the process conditions of:

MO Vent: 3 SLM

Rotation Purge: 30 SLM

Liner Purge: 5 SLM

Slit Valve Purge: 5 SLM

Pyro Purge: 6 SLM

Hydride Carrier N2: 5 SLM

MO Carrier N2: 5 SLM

Chamber pressure: 300 torr

Rotation: 0 rpm

Showerhead Chiller: 60° C.

Particle Trap: −20° C.

Lamp Zone Ratios: 14.2/28.3%

Returning to FIG. 9, the substrate carrier 914 may include one or more recesses 916 within which one or more substrates 940 may be disposed during processing. The substrate carrier 914 may carry one or more substrates 940. In one embodiment, the substrate carrier 914 carries eight substrates 940. It is to be understood that more or less substrates 940 may be carried on the substrate carrier 914. Typical substrates 940 may include sapphire, silicon carbide (SiC), silicon, or gallium nitride (GaN). It is to be understood that other types of substrates 940, such as glass substrates 940, may be processed. Substrate 940 size may range from 50 mm-300 mm in diameter or larger. The substrate carrier 914 size may range from 200 mm-750 mm. The substrate carrier 914 may be formed from a variety of materials, including SiC or SiC-coated graphite. It is to be understood that substrates 940 of other sizes may be processed within the chamber 902 and according to the processes described herein. The showerhead assembly 904, as described herein, may allow for more uniform deposition across a greater number of substrates 940 and/or larger substrates 940 than in traditional MOCVD chambers, thereby increasing throughput and reducing processing cost per substrate 940.

The substrate carrier 914 may rotate about an axis during processing. In one embodiment, the substrate carrier 914 may be rotated at about 2 RPM to about 100 RPM. In another embodiment, the substrate carrier 914 may be rotated at about 30 RPM. Rotating the substrate carrier 914 aids in providing uniform heating of the substrates 940 and uniform exposure of the processing gases to each substrate 940.

The plurality of inner and outer lamps 921A, 921B may be arranged in concentric circles or zones (not shown), and each lamp zone may be separately powered. In one embodiment, one or more temperature sensors, such as pyrometers (not shown), may be disposed within the showerhead assembly 904 to measure substrate 940 and substrate carrier 914 temperatures, and the temperature data may be sent to a controller (not shown) which can adjust power to separate lamp zones to maintain a predetermined temperature profile across the substrate carrier 914. In another embodiment, the power to separate lamp zones may be adjusted to compensate for precursor flow or precursor concentration non-uniformity. For example, if the precursor concentration is lower in a substrate carrier 914 region near an outer lamp zone, the power to the outer lamp zone may be adjusted to help compensate for the precursor depletion in this region.

The inner and outer lamps 921A, 921B may heat the substrates 940 to a temperature of about 400 degrees Celsius to about 1200 degrees Celsius. It is to be understood that embodiments of the invention are not restricted to the use of arrays of inner and outer lamps 921A, 921B. Any suitable heating source may be utilized to ensure that the proper temperature is adequately applied to the chamber 902 and substrates 940 therein. For example, in another embodiment, the heating source may include resistive heating elements (not shown) which are in thermal contact with the substrate carrier 914.

A gas delivery system 925 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 902. Different gases, such as precursor gases, carrier gases, purge gases, cleaning/etching gases or others may be supplied from the gas delivery system 925 to separate supply lines 931, 932, and 933 to the showerhead assembly 904. The supply lines 931, 932, and 933 may include shut-off valves and mass flow controllers or other types of controllers to monitor and regulate or shut off the flow of gas in each line.

A conduit 929 may receive cleaning/etching gases from a remote plasma source 926. The remote plasma source 926 may receive gases from the gas delivery system 925 via supply line 924, and a valve 930 may be disposed between the showerhead assembly 904 and remote plasma source 926. The valve 930 may be opened to allow a cleaning and/or etching gas or plasma to flow into the showerhead assembly 904 via supply line 933 which may be adapted to function as a conduit for a plasma. In another embodiment, MOCVD apparatus 900 may not include remote plasma source 926 and cleaning/etching gases may be delivered from gas delivery system 925 for non-plasma cleaning and/or etching using alternate supply line configurations to shower head assembly 904.

The remote plasma source 926 may be a radio frequency or microwave plasma source adapted for chamber 902 cleaning and/or substrate 940 etching. Cleaning and/or etching gas may be supplied to the remote plasma source 926 via supply line 924 to produce plasma species which may be sent via conduit 929 and supply line 933 for dispersion through showerhead assembly 904 into chamber 902. Gases for a cleaning application may include fluorine, chlorine or other reactive elements.

In another embodiment, the gas delivery system 925 and remote plasma source 926 may be suitably adapted so that precursor gases may be supplied to the remote plasma source 926 to produce plasma species which may be sent through showerhead assembly 904 to deposit CVD layers, such as III-V films, for example, on substrates 940.

A purge gas (e.g., nitrogen) may be delivered into the chamber 902 from the showerhead assembly 904 and/or from inlet ports or tubes (not shown) disposed below the substrate carrier 914 and near the bottom of the chamber body 903. The purge gas enters the lower volume 911 of the chamber 902 and flows upwards past the substrate carrier 914 and exhaust ring 920 and into multiple exhaust ports 909 which are disposed around an annular exhaust channel 4105.

The shaft cover reduces re-deposition to the showerhead because the shaft cover separates the lower dome and showerhead, which has the potential to prevent particles generated in the lower dome channel from re-depositing to the showerhead.

An exhaust conduit 906 connects the annular exhaust channel 905 to a vacuum system 912 which includes a vacuum pump (not shown). The chamber 902 pressure may be controlled using a valve system 907 which controls the rate at which the exhaust gases are drawn from the annular exhaust channel 905.

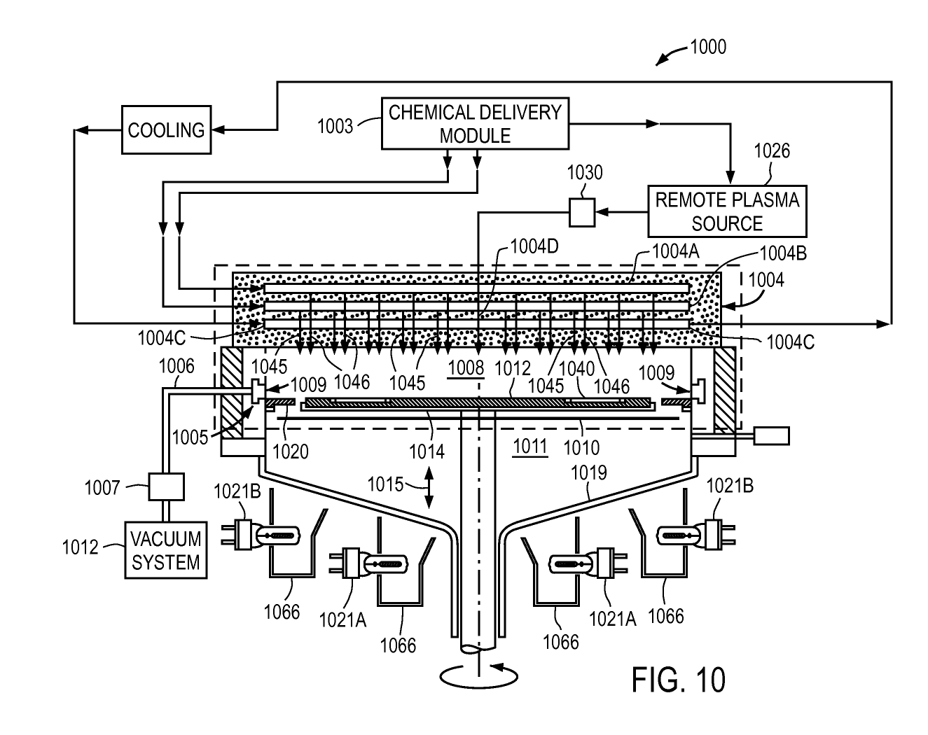

FIG. 10 is a schematic cross-sectional view of an MOCVD chamber in another embodiment. FIG. 10 includes similar components as described above for FIG. 9. FIG. 10 includes a more detailed cross sectional view of the showerhead assembly 1004. The showerhead assembly 1004 is located near the substrate carrier 1012 during substrate 1040 processing. In one embodiment, the distance from the showerhead face to the substrate carrier 1014 during processing may range from about 4 mm to about 50 mm. In one embodiment, the showerhead face may include multiple surfaces of the showerhead assembly 1004 which are approximately coplanar and face the substrates 1040 during processing.

During substrate 1040 processing, according to one embodiment, process gas flows from the showerhead assembly 1004 towards the substrate 1040 surface. The process gas may include one or more precursor gases as well as carrier gases and dopant gases which may be mixed with the precursor gases. The draw of the annular exhaust channel 1009 may affect gas flow so that the process gas flows substantially tangential to the substrates 1040 and may be uniformly distributed radially across the substrate deposition surfaces in a laminar flow. The processing volume 1008 may be maintained at a pressure of about 360 Torr down to about 80 Torr.

Reaction of process gas precursors at or near the substrate surface may deposit various metal nitride layers upon the substrate 1040, including GaN, aluminum nitride (AlN), and indium nitride (InN). Multiple metals may also be utilized for the deposition of other compound films such as AlGaN and/or InGaN. Additionally, dopants, such as silicon (Si) or magnesium (Mg), may be added to the films. The films may be doped by adding small amounts of dopant gases during the deposition process. For silicon doping, silane (SiH₄) or disilane (Si₂H₆) gases may be used, for example, and a dopant gas may include Bis(cyclopentadienyl)magnesium (Cp₂Mg or (C₅H₅)₂Mg) for magnesium doping.

The showerhead assembly 1004 receives gases via supply lines. The shaft cover 1010 is located below the suspector 1014. The use of the shaft cover 1010 beneath the process carrier reduces the lower dome 1019 coating and does not disturb the process conditions and the growth process in the chamber. Besides the lower dome coating by the growth process (e.g., LED growth process), it was found that some unwanted debris from the chamber or gaskets would also fall to the lower dome. During the high temperature operation, the fall-on debris will melt thus damaging and polluting the lower dome surface. The shaft cover 1010 prevents fall-on debris to lower dome.

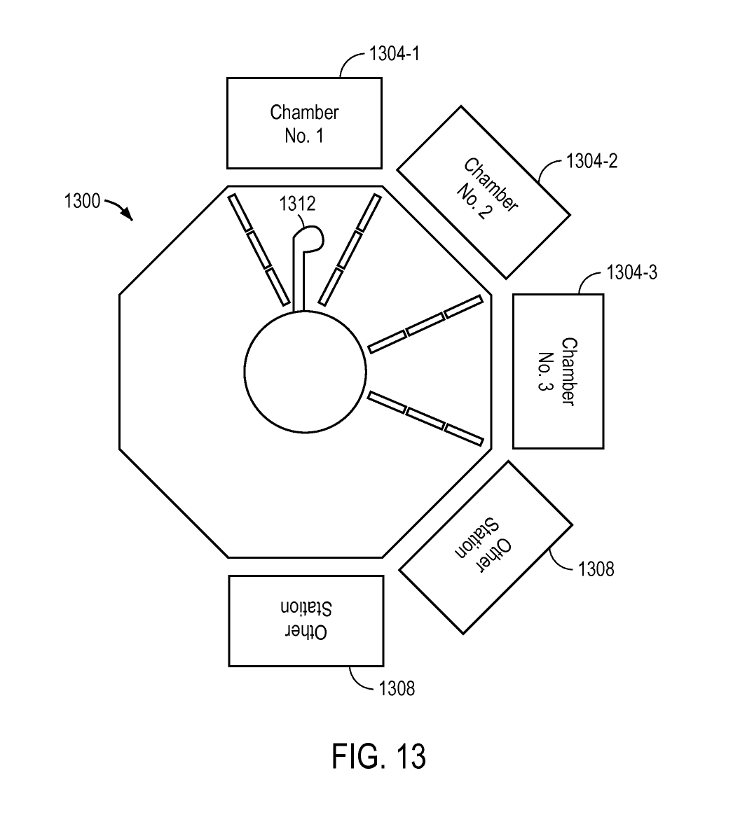

The HVPE apparatus 800, the MOCVD apparatus 900, and/or the MOCVD apparatus 1000 may be used in a processing system which includes a cluster tool that is adapted to process substrates and analyze the results of the processes performed on the substrate. The physical structure of the cluster tool is illustrated schematically in FIG. 13 in one embodiment. In this illustration, the cluster tool 1300 includes three processing chambers 1304-1, 1304-2, 1304-3, and two additional stations 1308, with robotics 1312 adapted to effect transfers of substrates between the chambers 1304 and stations 1308. The structure permits the transfers to be effected in a defined ambient environment, including under vacuum, in the presence of a selected gas, under defined temperature conditions, and the like. The cluster tool is a modular system including multiple chambers that perform various processing operations that are used to form an electronic device. The cluster tool may be any platform known in the art that is capable of adaptively controlling a plurality of process modules simultaneously. Exemplary embodiments include an Opus™ AdvantEdge™ system or a Centura™ system, both commercially available from Applied Materials, Inc. of Santa Clara, Calif.

For a single chamber process, layers of differing composition are grown successively as different steps of a growth recipe executed within the single chamber. For a multiple chamber process, layers in a III-V or II-VI structure are grown in a sequence of separate chambers. For example, an undoped/nGaN layer may be grown in a first chamber, a MQW structure grown in a second chamber, and a pGaN layer grown in a third chamber.

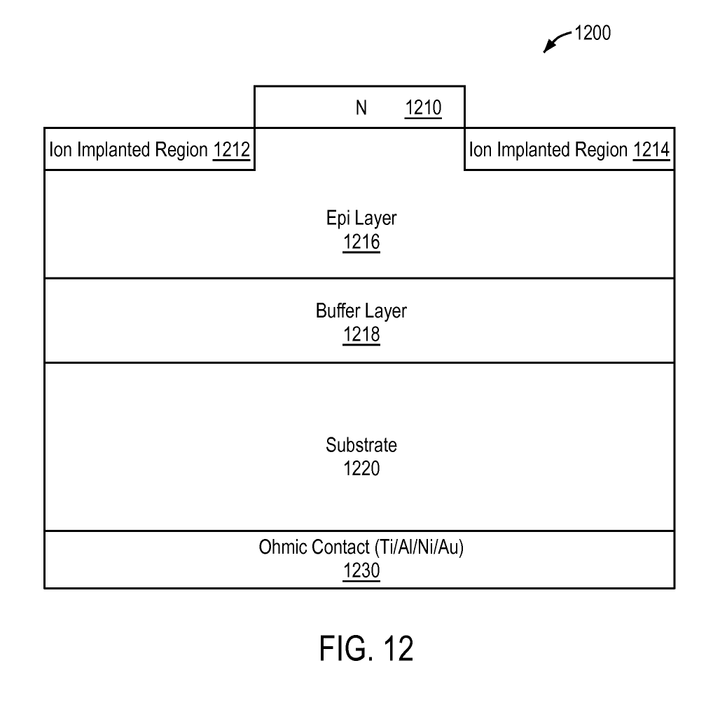

FIG. 12 illustrates a cross-sectional view of a power electronics device in accordance with one embodiment. The power electronic device 1200 may include an N type region 1210 (e.g., electrode), ion implanted regions 1212 and 1214, an epitaxial layer 1216 (e.g., N type GaN epi layer with a thickness of 4 microns), a buffer layer (e.g., N+GaN buffer layer with a thickness of 2 microns), a substrate 1220 (e.g., N+bulk GaN substrate, silicon substrate), and an ohmic contact (e.g., Ti/Al/Ni/Au). The device 1200 may include one or more layers of GaN disposed on a GaN substrate or a silicon substrate. The device (e.g., power IC, power diode, power thyristor, power MOSFET, IGBT, GaN HEMT transistor) may be used for switches or rectifiers in power electronics circuits and modules.

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration. Accordingly, the specification and drawings are to be regarded in an illustrative sense rather than a restrictive sense.

What is claimed is:

1. A system for growing a semiconductor on a substrate, the system comprising:
a processing chamber to grow an epitaxial layer on the substrate, the processing chamber comprises,
a susceptor to support a substrate support, which supports the substrate;
a shaft coupled to the suspector to support the suspector; and
a plate member coupled to the shaft, the plate member positioned below the suspector and designed to prevent particles and debris from falling below the plate member.

2. The system of claim 1, wherein the processing chamber further comprises a lower dome positioned below the plate member, the plate member designed to prevent a coating from being deposited on the lower dome during processing deposition conditions.

3. The system of claim 1, wherein the plate member is designed to improve heating efficiency within the processing chamber.

4. The system of claim 3, wherein the plate member further comprises an upper surface and a lower surface with the upper surface having a convex or concave shape in order to create a lens effect and improve the heating uniformity within the processing chamber.

5. The system of claim 1, wherein the plate member further comprises an upper surface and a lower surface with the upper and lower surfaces having a convex or concave shape in order to create a lens effect and improve the heating uniformity within the processing chamber.

6. The system of claim 2, further comprising a heating source to generate light and transmit the light through the lower dome towards the substrate to heat the substrate.

7. The system of claim 6, wherein the plate member is designed to improve heating uniformity between the plate member and the substrate within the processing chamber, wherein the plate member is positioned below the suspector such that the plate member does not disturb the processing conditions in the processing chamber.

8. A system for processing a substrate, the system comprising:
a processing chamber to process the substrate, the processing chamber comprises,
an edge ring to support a substrate support, which supports the substrate;
a shaft coupled to the edge ring to support the edge ring; and
a plate member coupled to the shaft, the plate member positioned below the edge ring and designed to prevent particles and debris from falling below the plate member.

9. The system of claim 8, further comprising a lower dome positioned below the plate member, the plate member designed to prevent a coating from being deposited on the lower dome during processing deposition conditions.

10. The system of claim 8, wherein the plate member is designed to improve heating efficiency within the processing chamber.

11. The system of claim 10, wherein the plate member further comprises an upper surface and a lower surface with the upper surface having a pattern in order to refract light and improve the heating uniformity within the processing chamber.

12. The system of claim 11, wherein the plate member to prevent particles generated in a processing region below the plate member from re-depositing on the showerhead.

13. The system of claim 9, further comprising a heating source to generate light and transmit the light through the lower dome towards the substrate to heat the substrate.

14. The system of claim 13, wherein the plate member is designed to improve heating uniformity between the plate member and the substrate within the processing chamber.

15. A processing chamber to process a semiconductor substrate, the processing chamber comprises:
a substrate support to support the semiconductor substrate;
a support member coupled to the substrate support to support the substrate support; and
a plate member coupled to the support member, the plate member positioned below the substrate support and designed to improve heating efficiency within the processing chamber.

16. The processing chamber of claim 15, further comprising a lower dome positioned below the plate member, the plate member designed to prevent a coating from being deposited on the lower dome during processing deposition conditions.

17. The processing chamber of claim 15, wherein the plate member to prevent particles and debris from falling below the plate member.

18. The processing chamber of claim 15, further comprising a heating source to generate heat and transmit the heat towards the substrate to heat the substrate, wherein the plate member is designed to improve heating uniformity between the plate member and the substrate within the processing chamber.

19. The processing chamber of claim 18, wherein the plate member further comprises an upper surface and a lower surface with the upper surface having a ripple pattern in order to refract light and improve the heating uniformity within the processing chamber.

20. The processing chamber of claim 15, wherein the plate member further comprises an upper surface and a lower surface with at least of the upper and lower surfaces having a convex or a concave shape in order to create a lens effect and improve the heating uniformity within the processing chamber.
